(19) United States
(12) Patent Application Publication
(10) Pub. No.: US 2023/0387766 A1
(43) Pub. Date: Nov. 30, 2023

(54) WINDING OPTIMIZATION

(71) Applicant: ebm-papst Mulfingen GmbH & Co. KG, Mulfingen (DE)

(72) Inventors: Ralph WYSTUP, Künzelsau (DE); Philip KEMMET, Heilbronn (DE)

(21) Appl. No.: 18/249,608

(22) PCT Filed: Oct. 6, 2021
(86) PCT No.: PCT/EP2021/077557

§ 371 Date: Apr. 19, 2023

(30) Foreign Application Priority Data
Oct. 21, 2020 (DE) 10 2020 127 708.3

(51) Int. Cl. H02K 15/08; H02K 15/02; G06T 1/00

(52) U.S. Cl. CPC H02K 15/08; G06T 1/0007; H02K 15/02

(57) ABSTRACT

A method for producing a winding of a coil around a component, of an electric motor, wherein in order to produce the winding, at least one wire is guided over at least one arm encircling the component in a rotational movement in such a way that the wire is wound around the component in successive turns, wherein at least one image acquisition device and/or at least one computer unit provides information about the course of turns that have already been wound, wherein the arm is dynamically controlled in a type of movement different from the encircling rotational movement, in such a way that the turn currently being applied by the movement follows a determined turn course that is optimized with respect to previously applied adjacent turns.

### CROSS-REFERENCES TO RELATED APPLICATIONS

This application is a Section 371 National Stage Application of International Application No. PCT/EP2021/077557, filed Oct. 6, 2021, and published as WO 2022/084040 A1 on Apr. 28, 2022, and claims priority to German Application No. 10 2020 127 708.3, filed Oct. 21, 2020, the contents of both are hereby incorporated by reference in their entirety.

### BRIEF DESCRIPTION OF THE DRAWINGS

FIG. 1 shows a schematic cross-sectional representation of A winding process of a stator tooth or rotor tooth, in one example.

FIG. 2 shows a flowchart illustrating a sequence of a method according to one example.

### DETAILED DESCRIPTION

The present disclosure relates to a method for producing a winding of a coil according to the preamble of patent claim 1.

Various methods are known for producing a winding of a coil. For example, in the flyer winding technique, an electrical conductor, for example a wire, is guided by means of a so-called flyer arm around a stator tooth or rotor tooth and wound around it. In this method, the control of the flyer arm is carried out according to a fixed sequence, wherein the flyer arm is moved only in the direction of laying the wire, parallel to the outer surface of the stator tooth or rotor tooth. Although this allows a fast and cost-effective production process, it has the disadvantage that the laying of the wire follows a certain statistical scatter, since the winding speed is usually very high and the comparatively thin wire is not guaranteed to be in a uniform stacking sequence. As a result, the wire length consumed in finished windings and the resulting resistance of the winding of a coil varies in these methods by up to 8%.

If such a coil is used in electric motors, for example in electric motors of fans, while the exact number of turns of the winding is recorded during the winding and a characterization of the motor is thereby possible, the length of the wire varies from coil to coil, however, which causes the coils to exhibit different operating parameters and in some cases, too much wire to be used. In addition, if the wire length is too long, the ohmic resistance of the coil winding increases, which generates unnecessary heat losses during operation.

An object of the present disclosure is therefore to provide a method for winding a coil, which improves the reproducibility of the operating parameters and, in particular, reduces the material consumed in the production of electrical windings of coils.

This object is achieved in conjunction with the preamble of claim 1 according to one example by the characterizing features of patent claim 1.

For the purposes of the present disclosure, a flyer is understood to be a very fast rotating disk or a fast rotating arm for producing wire windings of coils. Other types of guides for applying windings of wire onto coils are also conceivable.

For the purposes of the present disclosure, a coil comprises a winding made of a wire.

Furthermore, for the purposes of the present disclosure, a winding comprises a plurality of turns, each in the form of one complete circuit around the coil core, e.g. the stator tooth or rotor tooth, with a wire loop.

The present disclosure provides a method for producing a winding of a coil around a component, for example a stator tooth or rotor tooth of an electric motor, wherein in order to produce the winding at least one wire is guided over at least one arm or the like, encircling the component in a rotational movement in such a way that the wire is wound around the component in successive turns, wherein at least one image acquisition device and/or at least one computer unit provides information about the course of turns that have already been wound, wherein the arm is dynamically controlled in a type of movement that differs from the encircling rotational movement, in such a way that the turn currently being applied by the movement follows a determined course which is optimized with respect to previously applied adjacent turns.

In order to obtain advantages of a winding technique by means of flyer arms while at the same time reducing the material requirement in terms of wire, a degree of freedom is created to minimize the wire length. This degree of freedom is the guiding of the flyer arms. These are not guided according to a fixed pattern, for example in a back and forth pattern, but in such a way that the falling of the turn is detected by means of an image acquisition device and the movement of the flyer arms is dynamically controlled. The wire can thus take the shortest path around the tooth of the stator or rotor.

It is advantageous that the wire can be wound very quickly, which can reduce the costs of a manufacturing process, for example by reducing the corresponding lead time. However, the fact that the course of the turn is always optimized means that material can be saved during the manufacturing process, which can also lead to a reduction in costs.

Preferably, the turn that has already been wound is followed directly by the new turn to be laid. In the event of a slight deviation from the desired pattern, which would be very time consuming to correct, the winding is carried out according to a predetermined pattern, which can reduce the total time required in the production of the winding of the coil.

In addition, an optimized wire length when operating the coil winding, for example within an electric motor, can reduce the electrical losses and thus the motor can be used more efficiently and cost-effectively.

Furthermore, the operational safety of the motor can be increased, since it is necessary to know the exact parameters of the electric motor, in particular the coils, in order to determine the rotor position in encoderless methods.

The use of an image acquisition device for obtaining the data is advantageous at the high speeds occurring in the production process, since data can be acquired quickly and in a contactless manner.

It is further provided that the optimized turn course is determined by individual evaluation of the data of the image acquisition device and/or by individual calculations from the computer unit.

This enables the controller to access the information of the computing unit and/or the data of the image acquisition device in line with demand. This increases the flexibility of the production process and can lead to better results in terms of minimizing the length of the wire used and/or minimizing the duration of the production process. The preferably individual evaluation or calculation will require appropriate computer capacities, but on the other hand, direct control instructions for individual cases can be generated to provide increased process reliability of the described method.

It is further provided that the image acquisition device evaluates information about the course of the already wound turns, in such a way that the actual circumference of individual turns is determined.

It is advantageous in this case that the actual circumference of individual turns is a quantity that can be determined quickly by means of the image acquisition device. From the knowledge of the circumference, the length of wire already used can be quickly calculated using simple formulae, which can reduce the time required for the computing power of the control system and thus for the production process.

It is further provided that the optimized turn course is the course of the current turn that has the smallest possible circumference compared to the adjacent turns.

The smallest possible circumference reduces the length of wire used and can therefore be advantageous in saving material during the production process.

It is further provided that the optimized turn path is the path with the smallest possible radial stacking number of turns compared to the adjacent turns.

This favors the application of the wire in a planar extension, compared to the application of the wire in a radial extension, e.g. as a stack. The advantage here is that this gives rise to a compact and denser winding with correspondingly shorter wire length. An accumulation of turns at certain points of the coil, in particular the stator tooth or rotor tooth, and thus a local thickening of the winding, can thus be avoided.

Furthermore, it is provided that the optimized turn course is a course with a possible step width relative to the preceding turn, that is weighted compared to the adjacent turns.

Favoring the production of the winding in a planar extension may require an estimation of a step width, to the effect that too large a step width improves the position of the turn to be applied, but on the other hand, increases the wire length used unnecessarily. How far away the next turn may be placed, therefore, must be weighed against various alternatives. By weighting the various possibilities for the position of a turn, an optimized course of the further turn can be decided on quickly and the required wire length can be reduced.

It is further provided that the computer unit comprises a storage unit and stores information about windings of previously produced coils, namely winding scenarios of finished windings, wherein the information is obtained from the controller of the arm and/or from the image acquisition device and, in particular, additional data in the form of the physical parameters achieved, such as wire length, resistance, current linkage of the wound coil etc., is acquired and stored as assigned to the winding scenario.

This allows the data generated during the manufacturing process of previously produced coils to be incorporated into the manufacturing process of future coils to be produced. By applying the resulting learning effects, in particular using an appropriate artificial intelligence system, the decision-making about the courses of turns in the production process can be continuously improved with the production of each additional coil.

It is further provided that the computer unit comprises information about windings of previously produced coils, namely winding scenarios of finished windings, wherein the optimized turn course is determined by a weighted evaluation of earlier winding scenarios.

This means that, in addition to the data acquired during the production of the winding of the coil, the data of the already manufactured coils are incorporated, after completion of their manufacturing process, into the decision-making process, in particular of an appropriate artificial intelligence system. The production process of the coils to be produced in the future can be improved as a result.

Furthermore, it is provided that the calculation of the optimized turn course compared to previously applied adjacent turns is determined in real time, preferably for each subsequent turn immediately before its application.

Real-time calculation enables a faster production process that is flexible at all times, thereby saving costs.

Furthermore, it is provided that the computer unit comprises an artificial intelligence system which weights and influences the determined turn course that is optimized compared to previously applied adjacent turns.

This enables the computing unit to detect, process and solve problems autonomously. By means of a continuous learning process of the computer unit, relationships within the production process of the winding of the coil that are not obvious can be detected early and more quickly. As a result, it is possible to draw conclusions autonomously and, based on this, to incorporate improved decisions into the production process, in particular in an appropriate artificial intelligence system.

It is further provided that a servo control of the movement of the winding arm, in particular of the winding arms, is carried out when starting the production of a winding on the basis of information from previously completed windings, in particular on the basis of earlier winding scenarios.

This can accelerate the winding process in such a way that time-consuming calculations for measuring the wire courses are reduced and replaced by a learned winding pattern.

In other words, a turn that has already been wound is always followed directly by a new turn to be laid. If a deviation from a predefined winding pattern is present, this deviation is corrected in favor of material savings. However, if the correction would take too much time, the winding is continued according to the predefined winding pattern.

Additional details of the present disclosure are described in the drawings on the basis of exemplary embodiments shown schematically.

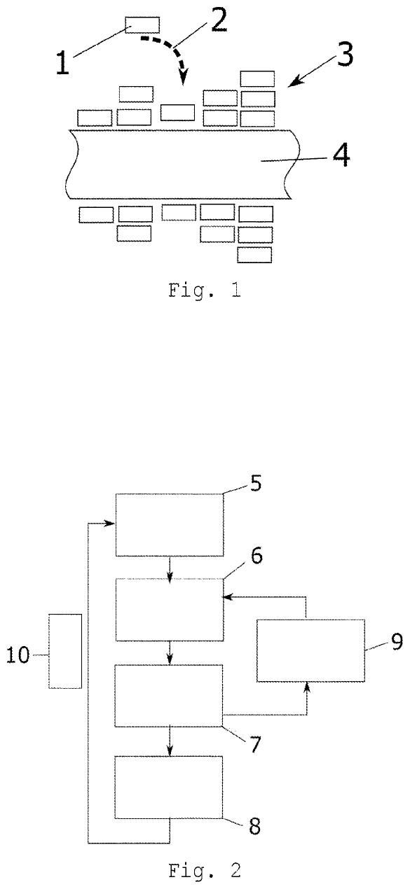

FIG. 1 schematically shows a stator tooth or rotor tooth (4) around which a wire is placed to generate a winding. A new turn (1) to be placed follows the already wound turns (3). A flyer arm (not shown), the movement of which is controlled, ensures that the new turn (1) describes a relative movement (2) in such a way that it comes to rest at a point on the tooth which, in spite of the crudely statistical “wild” winding technique, is optimized in favor of a minimized wire length and a fast production process. In order to determine this optimized position and to dynamically control the flyer arm accordingly, the placement of the new turn (1), as well as the already wound turns (3) of the coil, is recorded and evaluated by means of an image acquisition device (not shown). The optimal course of the wire is calculated at each time with the aid of an artificial intelligence system. This uses measurement data, for example regarding the wire resistance of already wound coils, to learn dynamically and improve its decisions.

FIG. 2 shows a flow diagram on the basis of which the method according to one example will be explained.

(5) First, an image acquisition device detects the wire course of already wound turns in the region adjacent to a new turn to be laid.

(6) Next, an image from the image acquisition device and/or data on already wound turns is evaluated. This generates knowledge about the actual circumference of the already wound turns (3) (shown in FIG. 1) in the region adjacent to a new turn (2) to be laid (shown in FIG. 1).

(7) Then a calculation of the expected circumference of the new turn (2) is carried out (shown in FIG. 1).

(8) Dynamic control of the flyer arms is then carried out for optimum laying of the new turn to be laid with a minimum circumference,

(9) as well as data acquisition for subsequent turns.

(10) This entire procedure is repeated for each additional turn.

Although the present invention has been described with reference to preferred embodiments, workers skilled in the art will recognize that changes may be made in form and detail without departing from the spirit and scope of the invention.

### LIST OF REFERENCE SIGNS

1 new/current turn to be laid
2 relative movement by flyer arm
3 already wound turns
4 stator tooth or rotor tooth
5 detection of the wire course
6 image evaluation
7 calculation of the expected circumference
8 control of the flyer arms
9 data acquisition for subsequent turns
10 repetition for each additional turn

1. A method for producing a winding of a coil around a component, of an electric motor,
wherein in order to produce the winding, at least one wire is guided over at least one arm encircling the component in a rotational movement in such a way that the wire is wound around the component in successive turns,
wherein at least one image acquisition device and/or at least one computer unit provides information about the course of turns that have already been wound,
wherein the arm is dynamically controlled in a type of movement different from the encircling rotational movement, in such a way that the turn currently being applied by the movement follows a determined turn course that is optimized with respect to previously applied adjacent turns.

2. The method according to claim 1, wherein the optimized turn course is determined by evaluation of the data of the image acquisition device and/or calculations from the computer unit.

3. The method according to claim 1, wherein the image acquisition device evaluates information about the course of the already wound turns in such a way that the actual circumference of individual turns is determined.

4. The method according to claim 1, wherein the optimized turn course is the course of the current winding that has the smallest possible circumference compared to the adjacent turns.

5. The method according to claim 1, wherein the optimized turn course is the course with the smallest possible radial stacking number of turns compared to the adjacent turns.

6. The method according to claim 1, wherein the optimized turn course is a course with a possible step width relative to the preceding turn that is weighted compared to the adjacent windings.

7. The method according to claim 1, wherein the computer unit comprises a storage unit and stores information about windings of previously produced coils, namely winding scenarios of finished windings, wherein the information is obtained from the controller of the arm and/or from the image acquisition device and additional data in the form of the physical parameters achieved is acquired and stored as assigned to the winding scenario.

8. The method according to claim 1, wherein the computer unit comprises information about windings of previously produced coils, namely winding scenarios of finished windings, wherein the optimized turn course is determined by a weighted evaluation of earlier winding scenarios.

9. The method according to claim 1, wherein the calculation of the optimized turn course compared to previously applied adjacent turns is performed in real time, for each subsequent turn immediately before its application.

10. The method according to claim 1, wherein the computer unit comprises an artificial intelligence system which weights and influences the determined optimized turn course compared to previously applied adjacent turns.

11. The method according to claim 1, wherein a servo control of the movement of the winding arms, is carried out when starting the production of a winding on the basis of information from previously completed windings, in particular on the basis of earlier winding scenarios.

12. The method according to claim 1, wherein the component comprises a stator tooth.

13. The method according to claim 1, wherein the component comprises a rotor tooth.

14. The method according to claim 7, wherein the physical parameters achieved comprises one or more of wire length, resistance, or current linkage of the wound coil.
